(19) United States
(12) Patent Application Publication
(10) Pub. No.: US 2010/0207227 A1
(43) Pub. Date: Aug. 19, 2010

(54) Electronic Device and Method of Manufacturing Same

(76) Inventor: Georg Meyer-Berg, Muenchen (DE)

Correspondence Address: INFINEON TECHNOLOGIES AG;Patent Department, MUC 11.1.507, P.O. Box 221644, Munich, 80506, DE

(21) Appl. No.: 12/371,646

(22) Filed: Feb. 16, 2009

(51) Int. Cl. H01L 31/0203; H01L 21/784

(52) U.S. Cl. 257/433; 438/465; 257/E21.703; 257/E31.117

(57) ABSTRACT

This application relates to a method of manufacturing a semiconductor device comprising providing a semiconductor wafer with the semiconductor wafer defining a first main face and a second main face opposite to the first main face; forming trenches in the first main face of the semiconductor wafer; forming a dielectric layer over the first main face and in the trenches; thinning the semiconductor wafer by removing semiconductor material from the second main face of the semiconductor wafer after the forming of the dielectric layer; and singulating at least one semiconductor chip from the semiconductor wafer along lines defined by the trenches.

### FIELD OF INVENTION

The present invention relates to a semiconductor device and methods of manufacturing semiconductor devices.

### BACKGROUND

Microelectronic manufacturing technology enables the integration of large arrays of electronic circuits, sensors, micro-electromechanical systems, laser diodes, and the like, into a semiconductor wafer. After integration on the wafer level, the wafers are singulated to break the arrays into individual separate chips. Singulation of the semiconductor wafers can create damage to the chips. Singulation becomes even more a challenge the thinner the chips, the smaller the chip size, or the smaller the feature sizes on the chips are.

### SUMMARY

Accordingly, there is provided a method of manufacturing a semiconductor device, comprising: providing a semiconductor wafer with the semiconductor wafer defining a first main face and a second main face opposite to the first main face; forming trenches in the first main face of the semiconductor wafer; forming a dielectric layer over the first main face and in the trenches; thinning the semiconductor wafer by removing semiconductor material from the second main face of the semiconductor wafer after the forming of the dielectric layer; and singulating at least one semiconductor chip from the semiconductor wafer along lines defined by the trenches.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A-1E schematically illustrate an embodiment of a method of manufacturing semiconductor devices wherein a trenches are formed in the first main face of the semiconductor wafer, a dielectric layer is formed over the first main face and in the trenches; and semiconductor material is thinned be the removal of semiconductor material from the second main face of the semiconductor wafer.

FIG. 2 schematically discloses an embodiment of a semiconductor wafer with trenches between the integrated circuits of an array of integrated circuits.

FIGS. 3A-3D schematically illustrate an embodiment of a method of manufacturing semiconductor devices wherein the semiconductor wafer comprises an array of integrated circuits, and the trenches are formed between the integrated circuits.

FIGS. 4A-4H schematically illustrate an embodiment of a method of manufacturing semiconductor devices wherein the dielectric layer formed on the first main face and in the trenches are structured for accessing the integrated circuits.

FIGS. 5A-5F schematically illustrate an embodiment of a method of manufacturing semiconductor devices wherein a dielectric layer is formed on the first main face and in the trench, and wherein the chips are singulated and subsequently covered with encapsulation material to form a second wafer.

### DETAILED DESCRIPTION

Although specific embodiments have been illustrated and described herein, it will be appreciated by those of ordinary skill in the art that a variety of alternate and/or equivalent implementations may be substituted for the specific embodiments shown and described without departing from the scope of the present invention. Generally, this application is intended to cover any adaptations or variations of the specific embodiments discussed herein. Therefore, it is intended that this invention be limited only by the claims and the equivalents thereof.

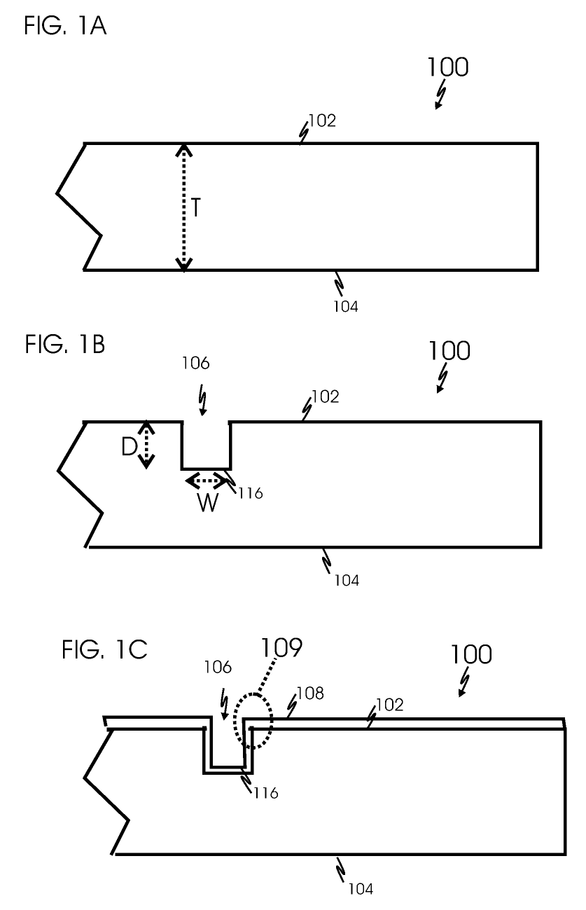

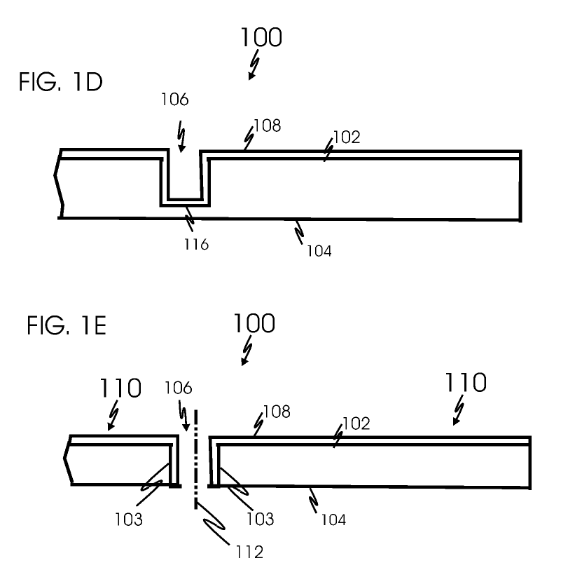

FIGS. 1A-1E depict an embodiment of a method of manufacturing a semiconductor device. FIG. 1A depicts a cross section through a section of a semiconductor wafer 100 having a first main face 102 and a second main face 104 opposite to the first main face. Semiconductor wafer 100 may be a monocrystal wafer made of silicon, germanium, gallium arsenide, or any other semiconducting material. In one embodiment, semiconductor wafer 100 is an essentially circular shaped disk complying with one of the standard disk diameters, e.g. 100 mm, 200 mm, 300 mm, 450 mm, or the like. The thickness T of semiconductor wafer 100 may be in a range of typically between 100 and 1000 micrometer, depending on the wafer material, the diameter and the application. In one embodiment, the wafer may have a diameter of 200 mm and a thickness of 725 micrometer; in another embodiment, the wafer may have a diameter of 300 mm and a thickness of 775 micrometer.

FIG. 1B depicts semiconductor wafer 100 of FIG. 1A after having formed trenches 106 in the first main face 102 of semiconductor wafer 100. Trenches 106 may be formed by any of the various known ways, e.g. by selective etching, by laser irradiation, by sawing with a sawing blade, etc.

The depth D of the trenches is defined by distance between first main face 102 and trench floor region 116. In one embodiment, depth D may be defined by the desired final thickness of the chips after singulation of the wafer. In one embodiment, the trenches have the same depth everywhere. For example, for applications like for power transistor chips, the thickness of the final chips is sought to be as small as 10 to 80 micrometer. Accordingly, trenches 106 may have a depth D of respective 10 to 80 micrometer. In other applications, depth D of trenches 106 may be 100 micrometer, 300 micrometer, or even larger. For example, for simplifying wafer singulation, depth D of trenches 106 may be chosen to be larger than one half of the thickness of wafer 100.

The width of trenches 106 may be freely chosen. For minimizing the loss of surface area to the trenches 106, it may be advantageous to keep the width of trenches 106 small. In one embodiment, if the trenches are formed by sawing, the width of the trenches may be given by the width of the sawing blade, which is typically 20 to 60 micrometer. A typical value for the trench aspect ratio, i.e. the ratio of trench depth D to trench width W of the trenches, is between 0.5 and 0.005.

FIG. 1C depicts semiconductor wafer 100 of FIG. 1B after a dielectric layer 108 has been formed on first main face 102 and in the trenches 106. In one embodiment, the walls of trenches 106 are completely covered with dielectric layer 108. This way, dielectric layer 108 can cover and mechanically protect the delicate trench edge regions 109 between trench 106 and first main face 102. At the same time, dielectric layer 108 can electrically insulate trench edge region 109 against conductors that may be applied to semiconductor wafer 100.

Dielectric layer 108 may be formed by any of various known ways. In one embodiment, dielectric layer 108 may be formed by spinning a liquid dielectric material onto the semiconductor wafer. In this case, the thickness of dielectric layer 108 on first main face 102 can be adjusted by the viscosity of the liquid dielectric material and by the speed by which the wafer is rotated when dispensing the liquid dielectric material. Typical values for the thickness of such dielectric layers on the surface of first main face 102 are 3 to 30 micrometer; however thickness may also be in a range between 1 and 100 micrometer. At the same time, the thickness of dielectric layer 108 may be different within the trenches 106. In one embodiment, dielectric layer 108 may be conformally disposed in the trenches 106 so that the thickness of dielectric layer 108 in the trenches is about the same as on wafer main surface 102. This situation is illustrated in FIG. 1C. On the other hand, depending on the type of layer application and layer material, trenches 106 may be partially or fully filled with liquid dielectric material after application of the dielectric layer material to the wafer.

In one embodiment, the dielectric material spun or sprayed on semiconductor wafer 100 may be a polymer. In one embodiment, the dielectric material may be a photoresist (e.g. PMMA, TMMR or Nano SU8). A photoresist has an advantage in that it can be structured easily by using standard photolithographic processing methods.

In one embodiment, dielectric layer 108 may be formed by depositing the dielectric material from a gas phase. In one embodiment, dielectric layer 108 is formed in a chemical vapour deposition process (CVD), a plasma enhanced chemical vapour deposition process (PECVD), or a physical vapour deposition process (PVD). For example, dielectric layer 108 may be a silicon oxide that is deposited from a gas phase. The thickness of such layer may be in the range between 100 nanometer and 2 micrometer. A gas phase deposited silicon oxide layer provides for good coverage of the trench edges and trench walls, good electrically insulation and good thermal conductivity. Other chemical vapour depositable dielectric materials are silicon or nitride. In one embodiment, the dielectric layer may be formed by thermal oxidation of the wafer surface.

FIG. 1D depicts semiconductor wafer 100 of FIG. 1C during thinning. Thinning is carried out by removing semiconductor material from second main face 104 homogenously. In one embodiment, semiconductor wafer 100 is thinned until floor regions 116 of the trenches are reached so that semiconductor chips 110 singulate from semiconductor wafer 100 (see FIG. 1E). In this case, chip 110 has a first main face 102, a second main face 104 and a side face 103 connecting first main face 102 with second main face 104. The thickness of the singulated semiconductor chips 110 is essentially given by the depth D that the trenches 106 had before singulation.

In one embodiment, thinning of semiconductor wafer 100 is stopped shortly before the floor regions 116 of the trenches 106 are reached. In this case, wafer 100 remains integral after thinning. In this case, singulation of the semiconductor chips 110 may be carried out by an additional process, e.g. by breaking one or multiple chips 110 from semiconductor wafer 100, by selectively etching the backside 104 of wafer 100 in the trench floor 116 region, by sawing the trench region along the trenches 106, or by any other known means.

In one embodiment, semiconductor wafer 100 is thinned by grinding second main face 104 with one of the known grinding tools. In one embodiment semiconductor wafer 100 is thinned by polishing the second main face 104, by chemical-mechanically polishing (CMP) the second main face 104, and/or by etching second main face 104 without a mask. Also, any combination of the above thinning methods may be used. Note that trench 106 in FIG. 1E defines a line vertically to the paper plane.

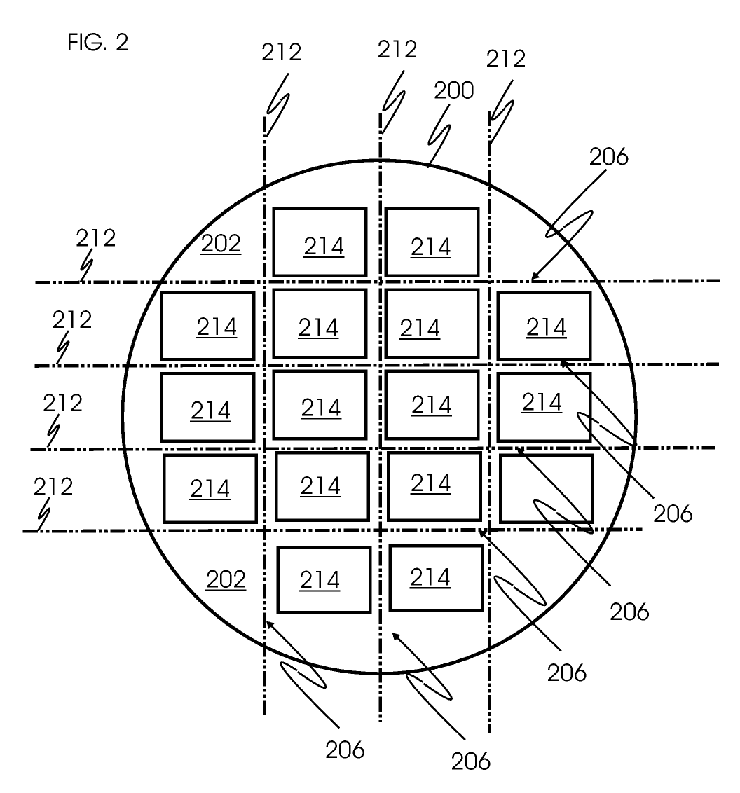

FIG. 2 schematically depicts an embodiment of a semiconductor wafer 200 with a view on its first main face 202. Wafer 200 may be the same wafer as wafer 100 described in FIGS. 1A-1E. Semiconductor wafer 200 may contain multiple integrated circuits 214 integrated into semiconductor wafer 200. In one embodiment, the multiple integrated circuits are arranged in a matrix like order.

In one embodiment, semiconductor wafer 200 is structured by multiple trenches 206 extending straight from one wafer edge position to another wafer edge position between the multiple integrated circuits 214. Depth and width of the trenches 206 may be the same as for the trenches 106 described in FIGS. 1A-1E. In particular, the depth of the trenches 206 on wafer 200 may be essentially the same everywhere. Each of the trenches 206 may define a line 212 along which multiple chips can be singulated to obtain multiple semiconductor chips.

In one embodiment, the trenches 206 may be divided into a first group of trenches extending into a first direction, and a second group of trenches extending into a second direction. The first group of trenches 206 and the second group of trenches 206 each define lines 212 that run parallel to each other. In one embodiment, the first direction is essentially orthogonal to the second direction. In this case, after singulation along the lines 212 defined by the trenches 206, the singulated chips 212 have a rectangular or quadratic shape. Obviously, the number of trenches 206 obtained after singulation may vary widely depending on the application, wafer size and desired chip size. For example, for the production of small integrated circuit chips from large wafers, the wafer may have fifty or more trenches in one direction and fifty or more trenches in the other direction. This way, 2500 or more chips can be singulated from a single wafer.

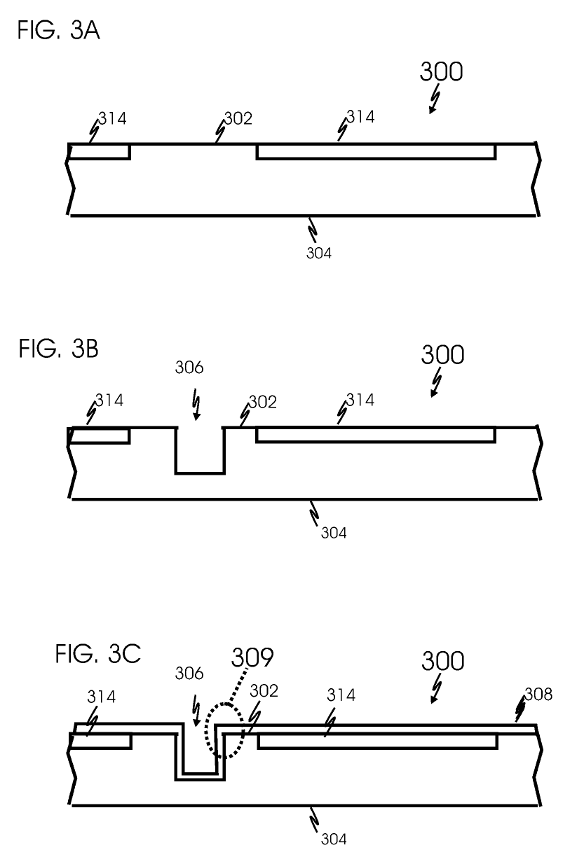

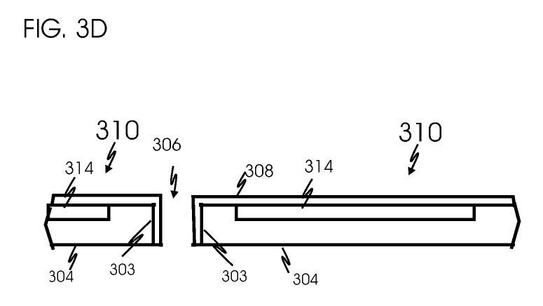

FIGS. 3A-3D schematically depict an embodiment wherein a semiconductor wafer 300 with an array of integrated circuits 314 is singulated into multiple chips 310 by means of trenches 306. Semiconductor wafer 300 may, or may not, be the same wafer as the one described in FIG. 2.

FIG. 3A depicts a section of semiconductor wafer 300 having multiple integrated circuits 314 integrated on first main face 302. The multiple integrated circuits 314 may be spaced apart from each other, and distributed as an array of rows and lines on first main face 302. Instead of an array of integrated circuits, semiconductor wafer 300 may also have an array of sensor elements, an array of micro-electromechanical system (MEMS) structures, an array of laser diodes, or arrays of other elements that can be integrated into semiconductor wafers by means of a planar micromechanical manufacturing process. The thickness of the wafer may have a value in a range between 100 and 1000 micrometer.

FIG. 3B depicts the section of semiconductor wafer 300 of FIG. 3A after trenches 306 have been formed on first main face 302 between adjacent integrated circuits 314. In one embodiment, the trenches 306 may consist of a first group of trenches that extend in parallel in a first direction, and a second group of trenches that extend in parallel in a second direction orthogonal to the first direction, as was described in FIG. 2. This way, trenches 306 may serve as defining lines that represent predetermined lines for singulating rectangular semiconductor chips 110 from the wafer 300, as was described in FIG. 2. In the embodiment of FIG. 3B, the trenches may have a depth of, say, 80 micrometer and a width of 30 micrometer. The depth D of trenches 306 is chosen to be slightly larger than a desired thickness of the chips after singulation. The production of the trenches may be carried out, for example, by a dry etching process selective to a mask.

FIG. 3C depicts the section of semiconductor wafer 300 of FIG. 3B after a dielectric layer 308 has been formed on first main face 302 and in trenches 306. In this embodiment, trenches 306 have been formed by a silicon oxide material deposited in a Chemical Vapor Deposition (CVD) process. This process provides good coverage of the walls of the trenches 306 and the trench edge region 309. The rigid structure of the silicon oxide material helps to protect the chips against chipping in the trench edge regions 309. The good electrical insulation also helps to electrically insulate the rim of the chips against electric shorts during chip operation.

FIG. 3D depicts the section of semiconductor wafer 300 of FIG. 3C after a grinding step has been carried out to homogeneously remove silicon material from second main face 304 until the floor of the trenches 306 has been reached. In one embodiment, the trenches fully surround each of the integrated circuits. In one embodiment, the trenches have the same depth throughout the wafer. In this case, when thinning semiconductor wafer 300 until the floor of the trenches 306 has been reached, the wafer 300 breaks into multiple semiconductor wafer chips 310 having a first main face 302, a second main face 304, and a side face 303 connecting first main face 302 with second main face 304. In this case, the thickness of the chips 310 ends up being slightly less than the depth of the original trenches 306.

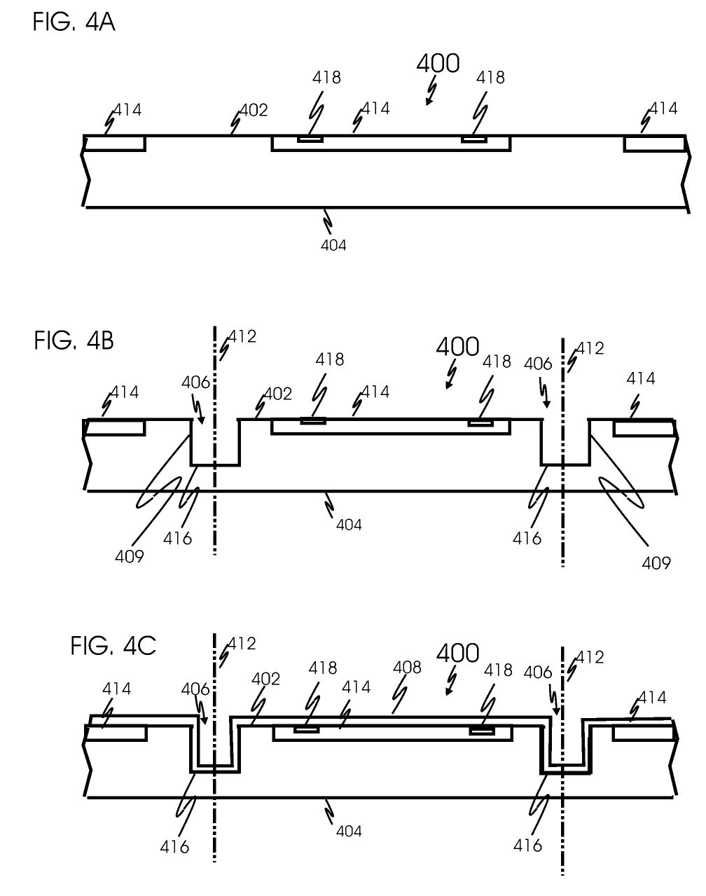

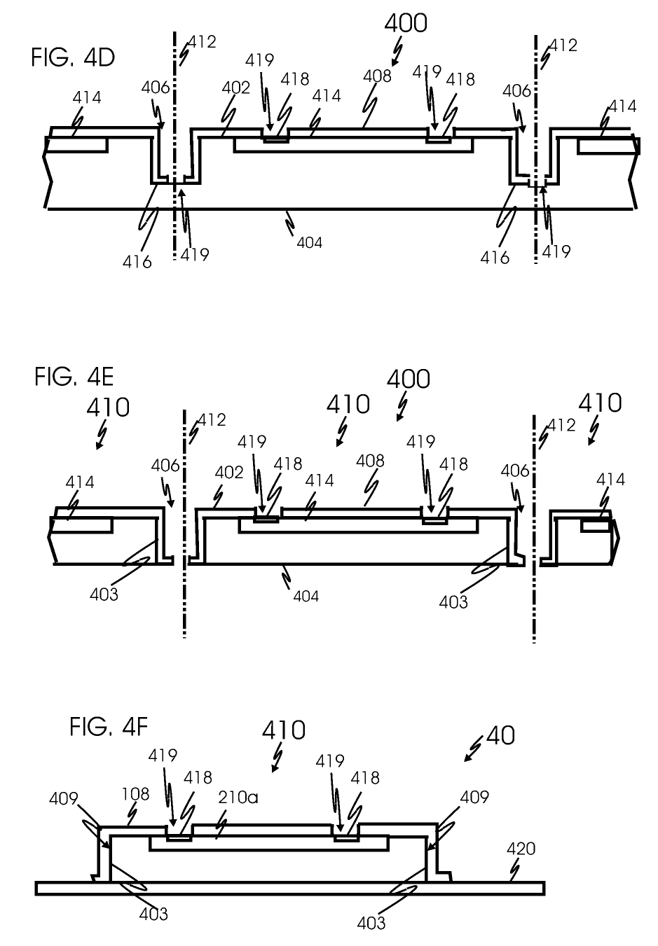

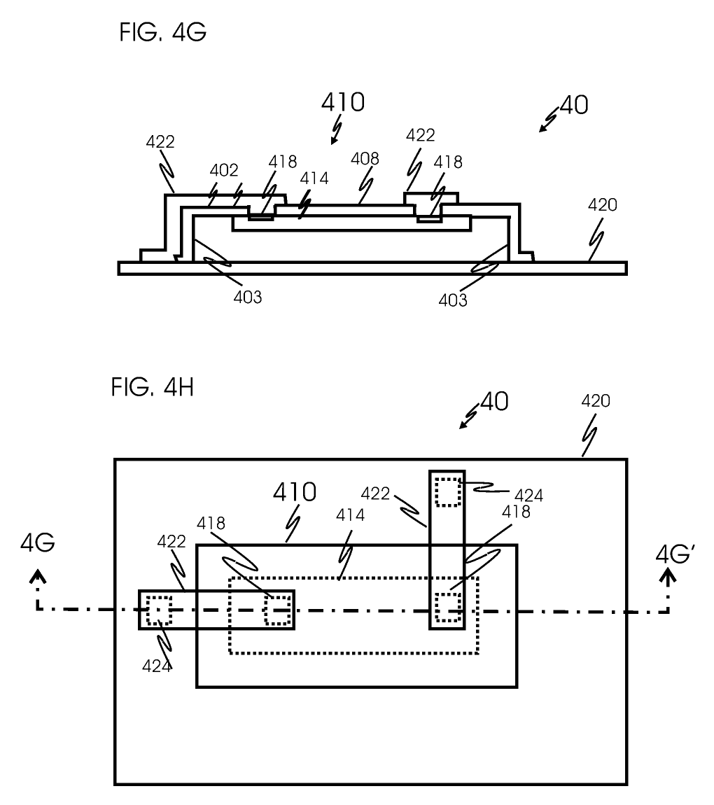

FIGS. 4A-4H schematically illustrate an embodiment wherein a semiconductor wafer 400 with an array of integrated circuits 414 is singulated into multiple chips 410 by means of trenches 406 onto which a dielectric layer 406 is applied and structured.

FIG. 4A schematically depicts a cross section through a segment of semiconductor wafer 400 having a first main face 402 and a second main face 404 opposite to first main faces 402. Semiconductor wafer 400 may or may not be the same as semiconductor wafer 300 of FIGS. 3A-3D. FIG. 4A discloses three of multiple integrated circuits 414 integrated on first main faces 402. Each of the integrated circuits has contact elements 418 for enabling external electrical connection with the respective integrated circuit.

FIG. 4B schematically depicts a cross section through semiconductor wafer 400 of FIG. 3A after trenches 406 have been formed in first main face 403 between adjacent integrated circuits 414. Each of the trenches defines a trench floor 416 and a trench edge 409 connecting trench floor 416 with first main face 402. The trenches 406 may or may not have a depth and width of the trenches 306 disclosed in FIGS. 3A-3D. Further, the trenches 406 may define lines 412 extending in parallel in a first direction on the wafer surface from one edge location of the wafer 400 to another edge location of the wafer, and lines 412 extending in parallel in a second direction on the wafer surface orthogonal to the first direction from one edge location of the wafer 400 to another edge location of the wafer, as shown in FIG. 2.

FIG. 4C schematically depicts a cross section through semiconductor wafer 400 of FIG. 4B after dielectric layer 408 has been applied conformally over the surface of first main face 406 and the walls of the trenches 406. In another embodiment, dielectric layer 408 may be applied non-conformally.

In one embodiment, dielectric layer 408 comprises photosensitive material. In this case, the dielectric layer can be structured easily by using a photolithographic process. In one embodiment, the photosensitive material may be a photoresist (e.g. PMMA or TMMR), a photoimid, a solderstop, Nano SU8 or a combination thereof. In one embodiment, dielectric layer 408 is formed by dispensing a liquid that contains the photosensitive material over the spinning wafer (spin-on). The thickness of the dielectric layer may be in a range between 3 and 30 micrometer, or more, depending on the application and on the type of the dielectric layer material used.

FIG. 4D schematically depicts a cross section through semiconductor wafer 400 of FIG. 4C after dielectric layer 408 has been structured for exposing the floor region 416 of the trenches and the contact elements 418 of the integrated circuits 414. This way, it is possible to access the integrated circuits 414 for electrical connection. The structuring may be carried out in traditional ways, e.g. by a photolithographic process.

FIG. 4E schematically depicts a cross section through semiconductor wafer 400 of FIG. 4D after thinning. Thinning is carried out by means of grinding second main face 404 of wafer 400, or by a chemical-mechanical planarization (CMP) process applied to second main face 404. In one embodiment, thinning is carried out until the floor regions 416 of the trenches 406 are reached and multiple semiconductor chips 410 are singulated from wafer 400. In this case, singulation occurs along the lines 412 defined by the trenches 406.ln other embodiments, instead of a CMP process, wafer 400 may also be thinned by grinding, or any other known way.. Note that due to dielectric layer 418 covering first main surface 402 and the trenches 406, the sensitive surfaces of the integrated circuits 414 and the trench etches 409 are mechanically protected during the thinning process.

FIG. 4F schematically depicts a cross section through one of the semiconductor chips 410 of FIG. 4E with the chip 410 attached to a carrier 420 with first main face 402 facing away from carrier 404. Chip 410 attached to a carrier 420 forms semiconductor device 40. The attachment may be carried out in known ways that depend on the type of carrier. For example, semiconductor chip 410 may be attached to carrier 420 by gluing or, if semiconductor chip 410 is to be attached to a metal surface, by soldering, sintering, and the like. Carrier 420 may be any of the carriers known in the art, e.g. a laminate substrate, a printed circuit board, a ceramic carrier, a copper carrier, and the like.

FIGS. 4G and FIG. 4H schematically illustrates the embodiment of FIG. 4F after structured metal layer 422 has been applied to semiconductor chip 410 and carrier 420. FIG. 4G depicts a cross section through the semiconductor chips 410 and carrier 420 of FIG. 4H along cross section line 4G-4G′ while FIG. 4H schematically depicts a view onto the chip and carrier of FIG. 4G.

In one embodiment, structured metal layer 422 is applied by applying a conformal metal layer to dielectric layer 408, the contact elements 418 and carrier 420. Metal layer application may be carried out by sputtering, vapour deposition, galvanisation, printing, and the like. The conformal metal layer application makes sure that the sides 403 of semiconductor chip 410, i.e. the former trench edges 409, are covered so that an electrical connection is provided between carrier 420 and chip 410. Then, after metal layer application, the metal layer may be selectively etched relative to a mask (not shown) so that a structured metal layer 422 is formed, as shown in FIG. 4H. In FIG. 4H metal layer 422 is structured so that two metal lines 422 are formed. In this case, each of the two metal lines 422 connect contact element 418 of chip 410 with a contact element 424 of carrier 420. The contact elements 424 of the carrier 420 in turn can be connected to pins, solder balls, a voltage source and other terminals. In this case, carrier 420 may serve as an interposer between the integrated circuit on the chip and the outside world. In many cases, semiconductor device 40 of FIGS. 4G and 4H may be encapsulated or housed later for mechanically and environmentally protecting the chip.

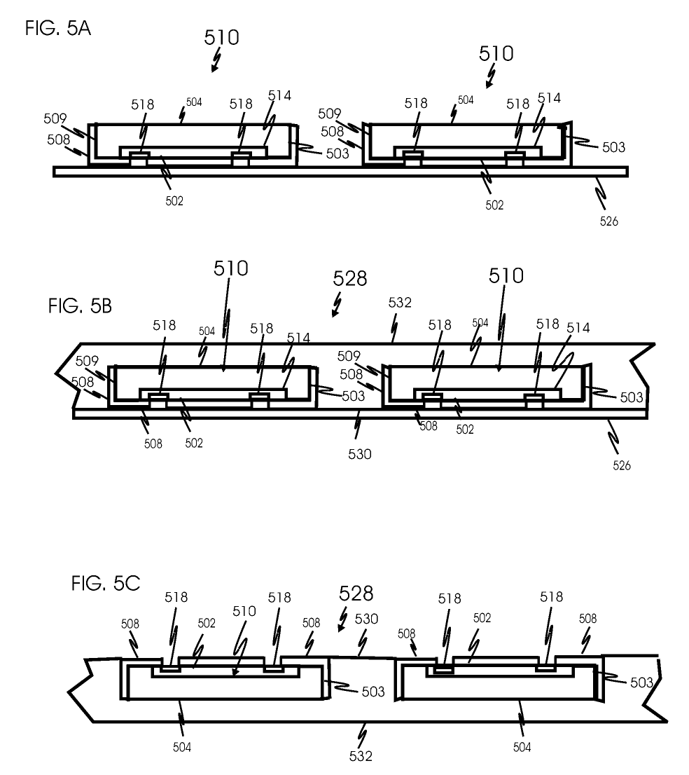

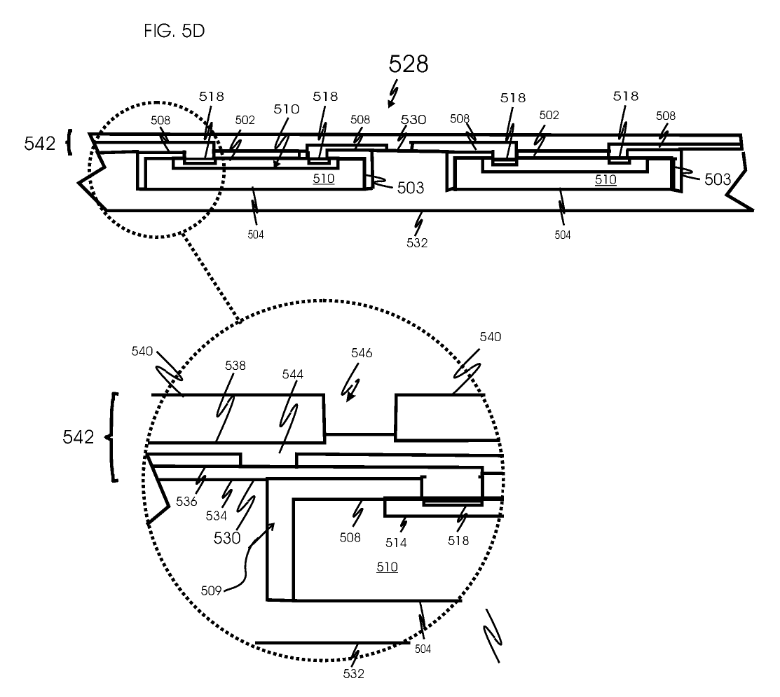

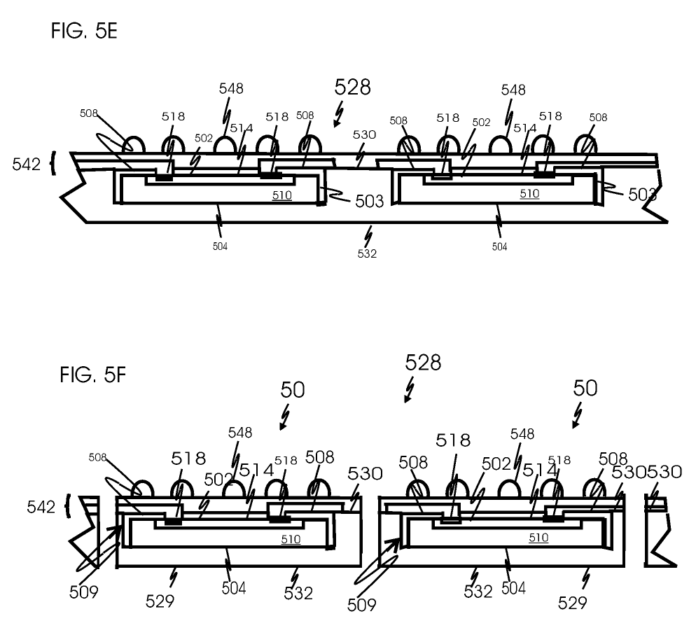

FIGS. 5A-5F schematically illustrate an embodiment wherein multiple semiconductor chips 510 of the type shown in FIG. 4E are encapsulated in a cost efficient manner.

FIG. 5A schematically depicts multiple semiconductor chips 510 that may or may not be the produced in the same way as described in FIGS. 4A to 4H. Like in FIG. 4E, semiconductor chip 510 has a first main face 502, a second main face 504 opposite to first main face 402, and a side face connecting first main face 502 with second main face 504. Semiconductor chip 510 further has an integrated circuit 514 and multiple contact elements 518 integrated into first main face 502. Each of the chips 510 has a dielectric layer 508 covering at least partially first main face 502 and chip edge 509. Dielectric layer 508 may or may not have been applied to semiconductor chip 510 in the same way as described in FIGS. 4C-4E. For example, dielectric layer 508 may be a photosensitive layer which can be structured by a photolithographic process without using an etching process. Alternatively, dielectric layer 508 may be, for example, an an organic insulation layer that may have been applied by vapour deposition or thermal oxidation. In one embodiment, dielectric layer 508 is structured to expose the contact pads 508 of the chips 510.

FIG. 5A schematically further discloses the multiple semiconductor chips 510 being attached to a first carrier 526 with their first main face 502 facing first carrier 526. In one embodiment, attachment of chip 510 with first carrier 526 may be carried out by the use of an adhering tape with adhering surfaces on both sides of the tape. I one embodiment, the adhering tape can be made non-adhering by electromagnetic irradiation (e.g. UV-irradiation), or after a heating process. First carrier 526 may be a planar plate 17a made, for example, of a metal, plastic and the like. First carrier 526 may also be a part of a mold form used for encapsulating the multiple chips 510. In this case, the surface of the mold form part may have a planar surface to make sure that during a subsequent encapsulation process, the encapsulation body has a surface coplanar with the surface of dielectric layer 508 on first main face 402.

FIG. 5B discloses the multiple semiconductor chips 510 of FIG. 5A after encapsulation of the multiple semiconductor chips 510 on first carrier 526 to form an encapsulation workpiece 528. Encapsulation may be carried out using the known transfer molding process, or compression molding process. For those processes, hot liquid encapsulation material is poured over the chips, or injected into a cavity in which the chips are placed. The temperature during this process may be in a range between 180 to 250 degrees Celsius, depending on the type of encapsulation material. Encapsulation material may be one of the known insulation polymer materials that are adapted for use as a semiconductor chip encapsulant. Note that during the cool down of the encapsulation material considerable mechanical forces may act on the semiconductor chips 510 due to the differences of the coefficients of thermal expansion (CTE) of semiconductor material and most polymer materials. Semiconductor chip 510 may be protected against those forces because of dielectric layer 508 covering and protecting the sensitive chip edge region 509.

In one embodiment, encapsulation is carried out with a mold form adapted to produce a disk-shaped encapsulation workpiece 528 having a first main face 530 and a second main face 532 opposite to first main face 530. With the chips 510 attached to first carrier 526 with their first main faces facing first carrier 526 during molding, the surface of dielectric layer 508 over the first main face 502 of the chip 510 is essentially coplanar with first main face 530 of the encapsulation workpiece 528. In an other embodiment, the mold form is adapted to produce a plate-like encapsulation workpiece 528 with, optionally, a rectangular plate shape.

FIG. 5C discloses encapsulation workpiece 528 of FIG. 5B after first carrier 526 has been removed from encapsulation workpiece 528. In the case that the semiconductor chips 510 are attached to first carrier 526 by means of an adhering tape that can be made non-adhering by UV-irradiation or heating, the surface of the chips has been irradiated or heated to detach first carrier 526 from encapsulation workpiece 528. As a result of the detachment, first main face 530 of encapsulation workpiece 528, dielectric layer 508 and contact elements 518 are exposed to the outside.

FIG. 5D discloses encapsulation workpiece 528 of FIG. 5C after a redistribution layer 542 has been applied to exposed first main face 530 of encapsulation workpiece 528 and to dielectric layer 508. Redistribution layer 542 may be used to fan-out the signal lines on the chip to positions away from the chip on the encapsulation workpiece 528. This way, additional space is provided for solder ball arrays that have to meet minimum solder ball pitch requirements.

As can be seen in the magnified picture segment of FIG. 5D, redistribution layer 542 consists of a first structured metal layer 534 applied to first main face 530 of encapsulation workpiece 528, to dielectric layer 508 and to contact elements 518 of semiconductor chip 510. Application of first structured metal layer 534 may be carried out by one of the known planar processes, e.g. by sputtering a metal onto encapsulation work piece 528 and a subsequent photolithographic structuring, by a selective galvanic process, and the like. Note that in the embodiment of FIG. 5D, first structured metal layer 534 is electrically connected with contact element 518 of integrated circuit 514. The thickness of first structured metal layer 534 may be in the order of a few hundred nanometer to a few ten micrometer, depending on the application and contact methods.

In the embodiment of FIG. 5D, redistribution layer 542 further consists of a first structured insulating layer 536 applied to first structured metal layer 534 for electrically insulating first structured metal layer 534 against a subsequently to be applied second structured metal layer 538. First structured insulating layer 536 may be applied by one of the known planar processes, e.g. by spinning an insulating polymer material over the first structured metal layer 534 and a subsequent photolithographic structuring process, and the like. Note that in the embodiment of FIG. 5D. The thickness of the first structured insulating layer 536 may be in the order of a few hundred nanometer to a few tens micrometer, depending on the application. The structuring of first structured insulating layer 536 also includes providing through-holes for making vias 544 between first structured metal layer 534 and second structured metal layer 538.

In the embodiment of FIG. 5D, redistribution layer 542 further consists of a second structured metal layer 538 applied to first structured insulating layer 536. Note that second structured metal layer 538 is not a requirement for a redistribution layer. However, a second structured metal layer 538 in a redistribution layer allows for additional routings, higher wiring density and crossing wiring lines. Second structured metal layer 538 may or may not be applied in the same way first structured metal layer 534. Note that the magnified picture segment shows one of the vias 544 that allow for electrical connection between wiring lines of the first and second structured metal layers.

In the embodiment of FIG. 5D, redistribution layer 542 further consists of a second structured insulating layer 540 applied to second structured metal layer 538 for electrically insulating second structured metal layer 538 against solder balls or other external contact to be applied subsequently. Second structured insulating layer 540 may or may not be applied in the same way as was first structured insulating layer 536. In the case that second structured insulating layer 540 is also to act as a solder stop layer for generating solder balls, thickness, structure and material used for second structured insulating layer 540 need to be adapted to this requirement. For example, if second structured insulating layer 540 is a solder stop layer, the thickness of second structured insulating layer 540 may have a layer thickness in the order of a few micrometer. In this case, the structuring of second structured insulating layer 540 may include providing openings 546 that can be used as reservoirs in the process for making solder balls from solder ball material deposited in the reservoirs.

FIG. 5E discloses encapsulation workpiece 528 after an array of solder balls 548 has been applied to redistribution layer 542. Application of solder balls to redistribution layer 542 can be done by known methods. For example, solder balls 548 can be formed by a reflow of solder material that was deposited in the solder material openings 546 (see magnificated segment of FIG. 5D). The diameter of the solder balls is typically in a range between 180 and 800 micrometer. In one embodiment, the diameter may be 500 micrometer with a solder ball pitch of 1000 micrometer. Not shown in FIG. 5E is that many, if not all solder balls 548 are electrically connected with the first or second structured metal layers 534, 538. Further, second structured metal layer 538 are electrically connected with the integrated circuits 514. The material of the solder balls may be one of the conventional materials used for solder balls, e.g. a SnPb alloy.

FIG. 5F discloses encapsulation workpiece 528 after singulation of multiple semiconductor devices 50 from encapsulation workpiece 528. Each semiconductor device 50 has a chip 510, a dielectric layer 508 covering chip edge region 509, a redistribution layer 542 covering dielectric layer 508, and a solder ball array 548 attached to redistribution layer 542. Each chip 510 is further embedded in encapsulation body 529. Singulation may be carried out by one of the conventional methods, e.g. sawing, selective etching, laser sawing, and the like. Depending on the size of the chips and the area of encapsulation workpiece 528, more than 10, 100 or thousands of semiconductor devices 50 may be singulated from encapsulation workpiece 528. For example, with encapsulation workpiece 528 having the shape of a 300 millimeter silicon wafer, and with the chips on encapsulation workpiece 528 being spaced apart with a pitch of 10 millimeter, about 400 semiconductor devices can be singulated from encapsulation workpiece 528.

Each of the semiconductor devices 50 obtained by the method described in FIGS. 5A-5F comprises at least one chip 510 having a first main face 502, a second main face 504 opposite to first main face 502, and a side face 503 connecting first main face 502 with second main face 504. Each of the semiconductor devices 50 has a dielectric layer 508 covering at least partially first main face 502 and side face 503, i.e. the former trench edge 509. Each of the semiconductor devices 528a, 528b further has at least a first structured metal layer covering dielectric layer 508. In one embodiment, dielectric layer 508 may be a photo-sensitive layer covering first main face 502 and edge region 509 of chip 510.

Further, each of the semiconductor devices 50 may have an integrated functional element 514, like an integrated circuit, an integrated sensor, or the like. Further, each of the semiconductor devices 50 may be embedded in an encapsulation body 529 singulated from encapsulation workpiece 528. Encapsulation body 529 may or may not be made of a polymer material. Encapsulation body 529 may have a first main face 530 facing away from second main face 504 of chip 510 and a second main face 532 facing away from first main face 502 of chip 510.

Semiconductor devices 50 further include contact elements 518 connected with integrated circuit 514. Further, photo-sensitive layer 508 has openings over each of the contact elements 518 so that redistribution layer 542 can be electrically coupled with integrated circuit 514. As described earlier, redistribution layer 542 is comprised of one or multiple structured metal layers 534, 538 over dielectric layer 508. Further, each semiconductor device 50 has an array of solder elements 548 electrically coupled with the structured metal layers 534, 538, and encapsulation material 532 encapsulating the chips 510.

It should be noted that for illustrational purposes, the figures of the semiconductor devices and figures describing the processes for manufacturing the semiconductor devices in this application are kept simple. Therefore, while the external contact elements shown in the figures are solder balls, the external contact elements may also be solder bumps, studs, pillars and related elements that are suitable for making contact to external devices, like a printed circuit board. Further, each of the semiconductor devices may also have two or more semiconductor chips.

Further, while a particular feature or aspect of an embodiment of the invention may have been disclosed with respect to only one implementation, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. The terms “coupled” and “connected”, along with derivatives may have been used. It should be understood that these terms may have been used to indicate that two elements co-operate or interact with each other regardless whether they are in direct physical or electrical contact, or they are not in direct contact with each other. Furthermore, it should be understood that embodiments of the invention may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

What is claimed is:

1. A method of manufacturing a semiconductor device, comprising:
providing a semiconductor wafer, the semiconductor wafer defining a first main face and a second main face opposite to the first main face;
forming trenches in the first main face of the semiconductor wafer;
forming a dielectric layer over the first main face and in the trenches;
thinning the semiconductor wafer by removing semiconductor material from the second main face of the semiconductor wafer after the forming of the dielectric layer; and
singulating at least one semiconductor chip from the semiconductor wafer along lines defined by the trenches.

2. The method according to claim 1 wherein the semiconductor wafer is thinned until floor regions of the trenches are reached.

3. The method according to claim 1 wherein the at least one semiconductor chip is singulated from the semiconductor wafer during the thinning of the semiconductor wafer.

4. The method according to claim 1 wherein the trenches are formed by at least one of selective etching, laser irradiation, and sawing.

5. The method according to claim 1 wherein the semiconductor wafer further comprises multiple integrated circuits within the first main face.

6. The method according to claim 5 wherein the trenches are formed between the multiple integrated circuits.

7. The method according to claim 1 wherein the dielectric layer is formed by at least one of spinning a dielectric material onto the semiconductor wafer, disposing the dielectric material from a gas phase, spraying, printing, and generating a thermal oxide layer.

8. The method according to claim 1 further comprising structuring the dielectric layer.

9. The method according to claim 1 wherein the dielectric layer comprises photo-sensitive material.

10. The method according to claim 1 wherein the dielectric layer comprises at least one of a photoresist, a photoimid, a solderstop, and Nano SU8.

11. The method according to claim 8 wherein the dielectric layer is structured for accessing multiple integrated circuits.

12. The method according to claim 8 wherein the dielectric layer is structured for exposing a floor region of the trenches.

13. The method according to claim 1 wherein the semiconductor wafer is thinned by at least one of grinding, polishing, chemical mechanical polishing, and etching.

14. A method of manufacturing a semiconductor device, comprising:
providing a semiconductor wafer, the semiconductor wafer defining a first main face comprising an array of integrated circuits, and a second main face opposite to the first main face;
forming trenches between the integrated circuits;
forming a dielectric layer over the first main face and in the trenches; and
thinning the semiconductor wafer until multiple semiconductor chips are singulated from the semiconductor wafer along lines defined by the trenches.

15. A semiconductor device comprising:
a chip having a first main face, a second main face opposite to the first main face, and a side face connecting the first main face with the second main face;
a photo-sensitive layer covering the first main face and the side face; and
a structured metal layer covering the photo-sensitive layer.

16. The semiconductor device according to claim 15 wherein the chip further comprises an integrated circuit and a contact element coupled with the integrated circuit.

17. The semiconductor device according to claim 16 wherein the photo-sensitive layer is opened over each of the contact elements.

18. The semiconductor device according to claim 15 further comprising an encapsulation body embedding the chip, the encapsulation body having a first main face and a second main face opposite to the first main face.

19. The semiconductor device according to claim 18 further comprising a structured metal layer extending over the first main face of the chip and the first main face of the encapsulation body.

20. The semiconductor device according to claim 19 further comprising an array of external contact elements coupled with the structured metal layer.

21. The semiconductor device according to claim 20 wherein the array of external contact elements is attached to the first main face of the semiconductor chip.

22. A semiconductor device, comprising:
a chip having a first main face, a second main face opposite to the first carrier, and a side face connecting the first main face with the second main face;
a photo-sensitive layer covering the first main face and the side face, an encapsulation body embedding the chip, the encapsulation body having a first main face and a second face opposite to the first face; and
a structured metal layer over the photo-sensitive layer and the first main face of the encapsulation body.

23. The semiconductor device according to claim 22 comprising an array of external contact elements coupled with the structured metal layer.

24. The semiconductor device according to claim 23 wherein the array of external contact elements is attached to the first main face of the chip and the first main face of the encapsulation body.
